(19) United States
(12) Patent Application Publication
(10) Pub. No.: US 2011/0120768 A1
(43) Pub. Date: May 26, 2011

(54) CONTROL UNIT

(76) Inventors: Thorsten Kremer, Gerlingen (DE); Michael Knorpp, Weissach (DE); Joerg Mayer, Backnang (DE)

(21) Appl. No.: 12/994,023

(22) PCT Filed: Mar. 25, 2009
(86) PCT No.: PCT/EP2009/053505

§ 371 Date: Jan. 31, 2011

(30) Foreign Application Priority Data
May 21, 2008 (DE) 1020080019151

(51) Int. Cl. H01R 4/02; H05K 13/00

(52) U.S. Cl. 174/84 R; 29/825

(57) ABSTRACT

A control unit according to the invention is particularly intended for internal combustion engines for motor vehicles. With known control units, great effort is required if the customer requests a different electric assignment for the electrical connection. With the control unit according to the invention, any arbitrary electric assignment of the pins can be achieved by simple measures at the electrical connection. This considerably simplifies meeting special customer requests.

### PRIOR ART

### Disclosure of the Invention

German Published Patent Disclosure DE 195 25 510 A1, U.S. Pat. No. 5,672,818, and Japanese Patent JP 38 42 336 B2 show a control unit with an electrical terminal. In the known control unit, the electrical terminal is formed by a plug-in terminal. From the plug-in terminal, there is a conductor track connection with a plurality of conductor tracks. One group of conductor tracks leads to a sensor with which the angle of rotation at the time of a throttle valve, pivotably supported in the control unit, can be sensed. Another group of conductor tracks leads to an electrical actuating drive, with which the rotated position at the time of the throttle valve can be adjusted. The conductor tracks of the conductor track connection are partly spray-coated with plastic and as a result are securely positioned in their position.

Each individual conductor track of the conductor track connection connects one terminal of the sensor or of the actuating drive to a special plug pin of the plug connection of the electrical terminal. Depending on the customer's request, it can happen that a certain terminal of the sensor is to be electrically connected to a particular plug pin of the plug connection. With changing customer requests, the effort and expense for modifying the connection between the pins of the plug connection and the applicable terminals of the sensor or of the actuating drive is fairly high.

German Patent Disclosure DE 195 40 323 A1 also shows a control unit with an adjustably supported body in the form of a throttle valve and with an electrical terminal in the form of a plug connection for connecting the control unit to an external electrical device; the electrical device is for example an electric control unit or an electric power supply.

### DISCLOSURE OF THE INVENTION

### Advantages of the Invention

The control unit of the invention having the definitive characteristics of claim 1 has the advantage over the prior art that by means of a simple provision, the electrical assignment of the electrical terminal can be adapted in a simple way to the electrical assignment requested by the particular customer. In a simple way, the particular requested electrical assignment can be associated with the electrically connected components of the control unit.

Because of the simple association in assigning the electrical terminal of the connected components of the control unit, great flexibility in the production of the control unit is advantageously achieved, and as a result, individual requests of a customer can be met at feasible effort and expense even when a small number of items is involved.

A further advantage is that the effort and expense in changing the spacing between the electrical terminal and one or more of the connected components is reduced.

By the provisions recited in the dependent claims, advantageous refinements of and improvements to the control unit defined by the main claim are possible.

If the conductor track connection has a plurality of intersection regions between the conductor tracks and the counterpart conductor tracks, then this advantageously substantially enhances the flexibility of the electrical assignment of the electrical terminal.

If the at least one conductor track and/or the at least one counterpart conductor track of the conductor track connection, in the at least one intersection region, is pivoted in the direction of the counterpart conductor track or of the conductor track, respectively, this offers the advantage that at this point, the conductor track can be electrically connected to the counterpart conductor track in a very simple way.

If the at least one conductor track or the at least one counterpart conductor track extends in the intersection region in planes that are disposed with little spacing from one another, this has considerable advantages in terms of the flexibility and the spatial association of the parts to one another.

If an adapter that electrically connects the conductor track to the counterpart conductor track is provided in the intersection region between the conductor track and the counterpart conductor track, this has the advantage that by either mounting or omitting the adapter, the electrical contact-making between the electrical terminal and the electrically connected components can be adapted quite flexibly to the various requirements. The adapter can advantageously be mounted very simply at each desired intersection region. Advantageously, this does not require modifying any shaping tool.

### BRIEF DESCRIPTION OF THE DRAWINGS

Preferably selected and especially advantageous exemplary embodiments of the invention are shown in simplified form in the drawings and described in further detail in the ensuing description.

FIG. 1 is an oblique view of the control unit;

FIG. 2 is an oblique view of the control unit with the clamshell housing removed;

FIG. 3 is an oblique view of the actuating drive in the interior of the control unit;

FIG. 4 is an oblique view of the conductor track connection inside the control unit;

FIG. 5 is an oblique view of details of the conductor track connection;

FIG. 6 is a view showing details of the conductor track connection in a subsequent production step;

FIG. 7 is a further view of details of the conductor track connection;

FIG. 8 is a modified embodiment of the conductor track connection; and

FIGS. 9A and 9B show details of a further embodiment of the conductor track connection.

### EMBODIMENTS OF THE INVENTION

The control unit embodied according to the invention can be used in any internal combustion engine in which the engine power is to be influenced with the aid of the control unit. For instance, with the control unit, the air supplied to the engine can be controlled. In that case, the control unit is typically a throttle valve stub with an adjustably supported throttle valve. The control unit may, however, also be used for instance for controlling exhaust gas and/or a lateral air conduit.

In all the drawings, parts that are the same or that function the same are identified by the same reference numerals. Unless otherwise mentioned or shown in the drawing, what is mentioned and shown in conjunction with one of the drawings applies to the other exemplary embodiments as well. Unless otherwise noted in the explanations, the details of the various exemplary embodiments can be combined with one another.

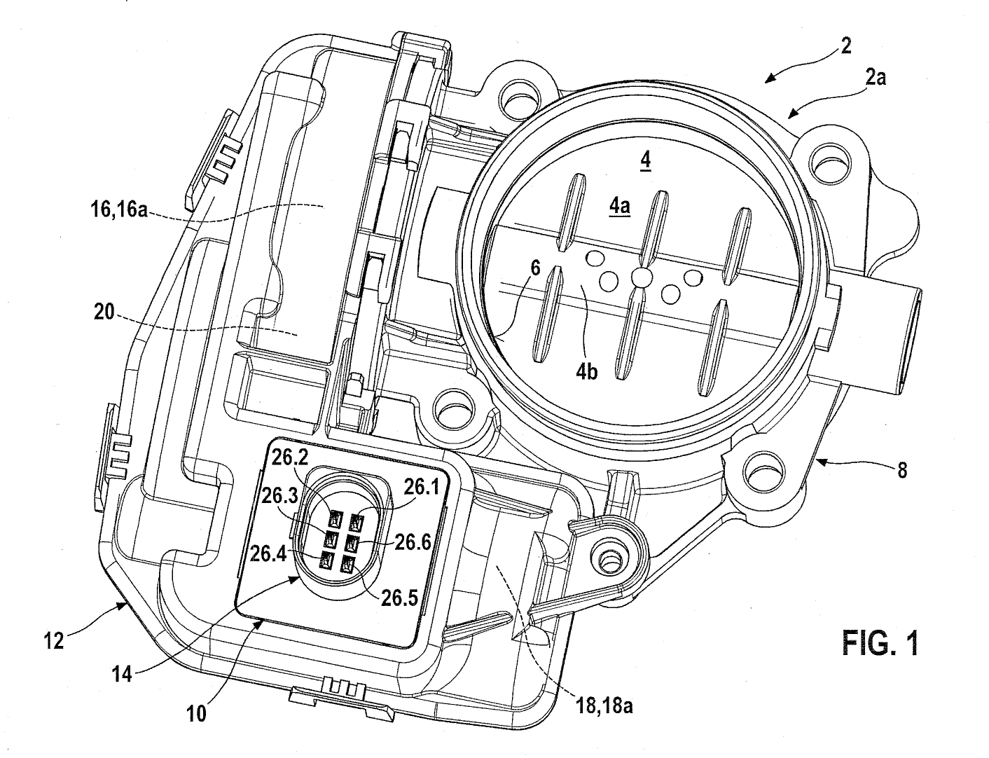

FIG. 1 shows a control unit 2 with an adjustably supported body 4. In the exemplary embodiment shown, the control unit 2 is a throttle valve stub 2a, and the adjustably supported body 4 is a throttle valve 4a. A gas conduit 6 extends through the throttle valve stub 2a. A throttle valve shaft 4b is supported pivotably in the control unit 2, or more precisely in the throttle valve stub 2a. The body 4, or more precisely the throttle valve 4a, is connected to the throttle valve shaft 4b in a manner fixed against relative rotation.

In rough terms, the control unit 2 or throttle valve stub 2a can be subdivided into a clamshell housing 8, a connection element 10, and a gearbox 12. An electrical terminal 14 is located on the connection element 10.

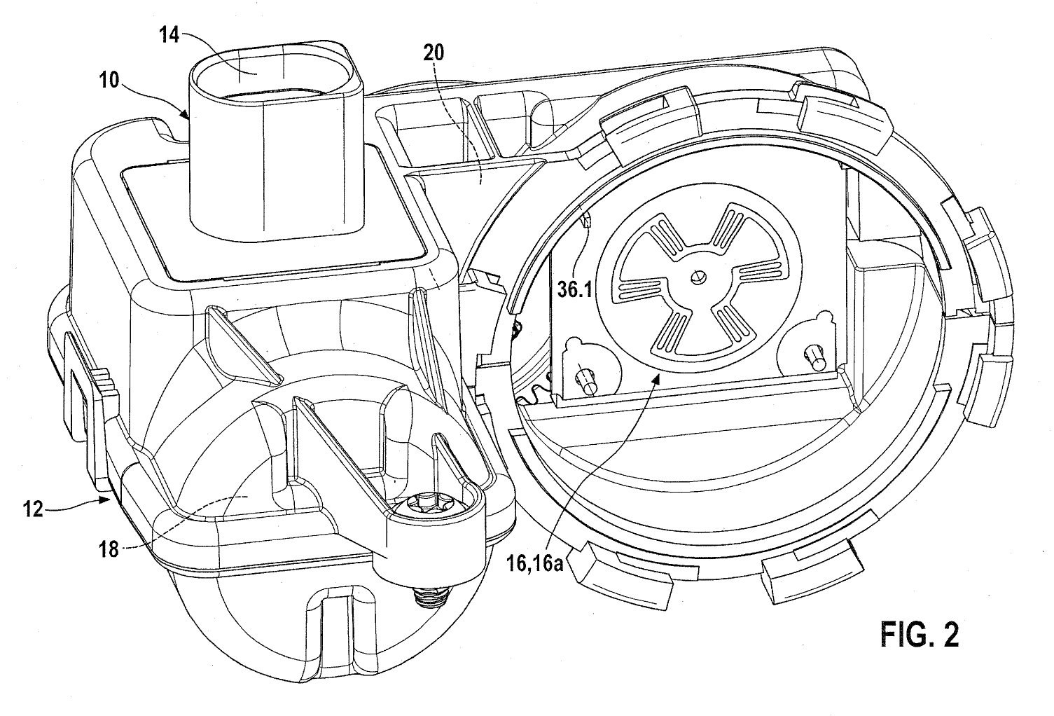

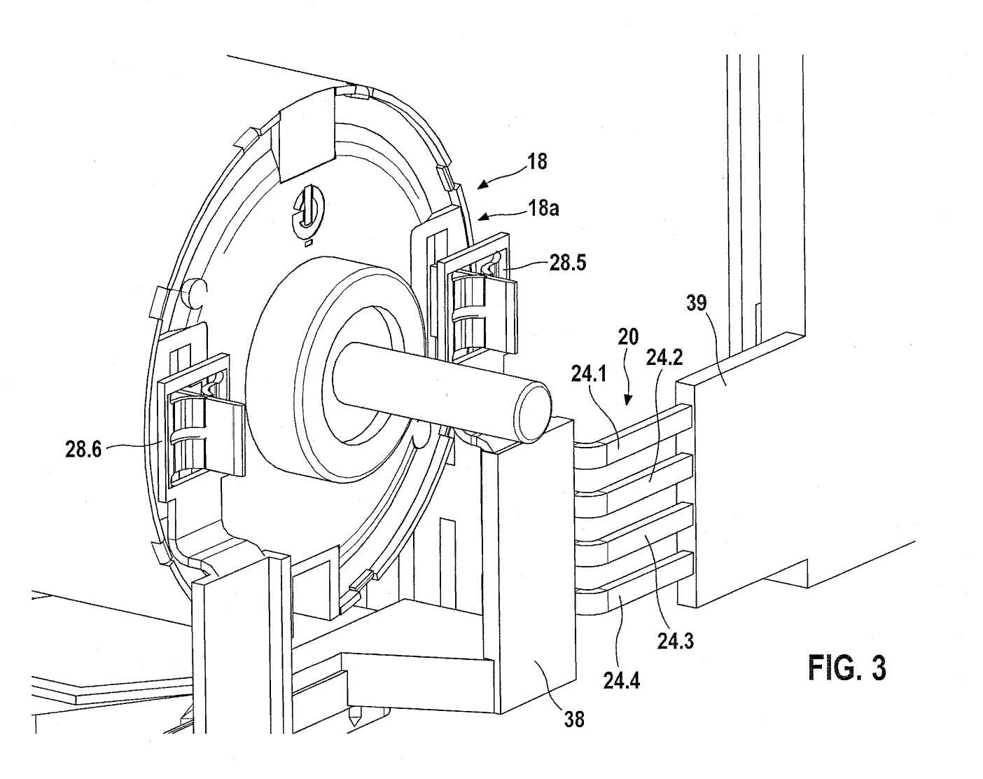

FIG. 2 shows the control unit 2 with the clamshell housing 8 removed, and FIG. 3 shows the control unit 2 with the clamshell housing 8 removed and with the gearbox 12 open.

Via the electrical terminal 14, at least one electrical component 16 is electrically connected. In the exemplary embodiment shown, the electrical component 16 is a sensor 16a (see FIG. 2) for sensing a position of the adjustably supported body 4, or more precisely for sensing the angular position of the throttle valve shaft 4b with the throttle valve 4a secured to it.

In the preferably selected exemplary embodiment, there is a further electrical component 18 in the gearbox 12 of the control unit 2. In the exemplary embodiment, the further electrical component 18 is an electrical actuating drive 18a. The actuating drive 18a can rotate the throttle valve shaft 4b and the throttle valve 4a, via a gear provided in the gearbox 12.

Via the electrical terminal 14 of the connection element 10, the control unit 2 can be connected for instance to an external electrical device, not shown for the sake of greater simplicity. The external electrical device, not shown, is for instance an electric or electronic control unit and/or a current or voltage supply. The electrical terminal 14 is part of a plug connection for connecting the control unit 2 to the external electrical device. The electrical terminal 14 of the connection element 10 is embodied as a plug-in coupling. The control unit 2, with a cable, not shown, and a counterpart plug-in coupling, not shown, can be connected quite simply to the external electrical device, not shown, via the electrical terminal 14.

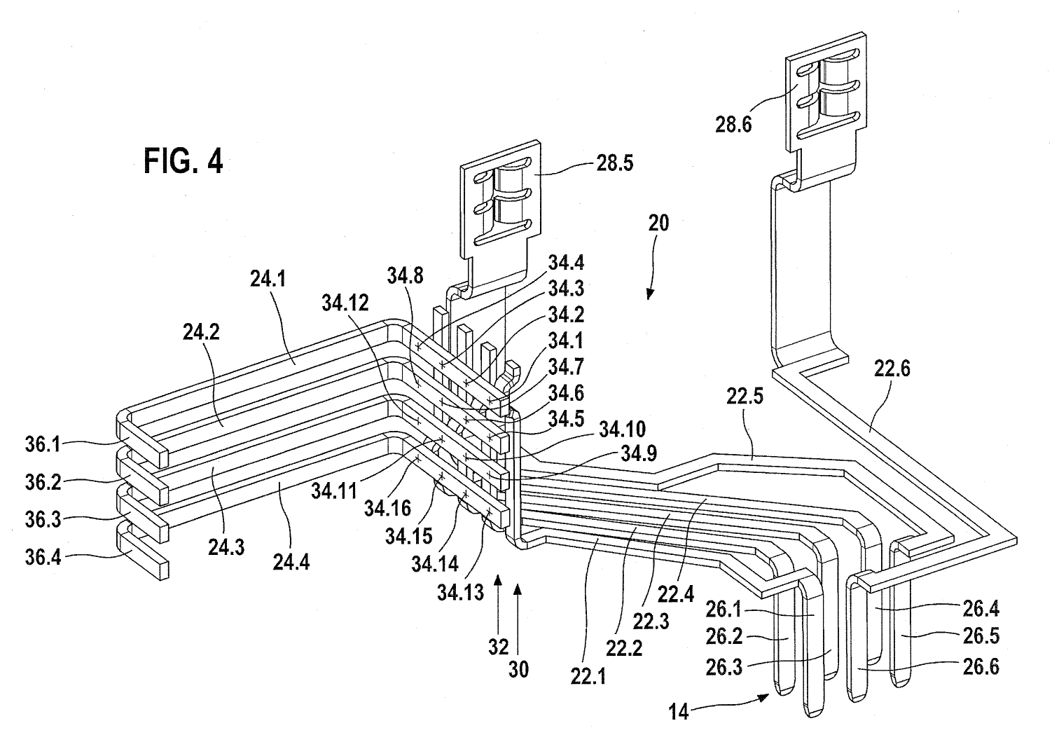

FIG. 4 shows a conductor track connection 20 during a production-dictated intermediate step.

In the finished control unit 2, the conductor track connection 20 is located inside the gearbox 12 of the control unit 2. In the exemplary embodiment, the conductor track connection 20 belongs to the connection element 10. The conductor track connection 20 substantially comprises at least one conductor track 22.1 and at least one counterpart conductor track 24.1. In the preferably selected exemplary embodiment, the conductor track connection 20 has six conductor tracks 22.1, 22.2, 22.3, 22.4, 22.5, 22.6 and four counterpart conductor tracks 24.1, 24.2, 24.3, 24.4 (see FIG. 4). The six conductor tracks 22.1, 22.2, 22.3, 22.4, 22.5, 22.6 of the conductor track connection 20 lead to six plug pins 26.1, 26.2, 26.3, 26.4, 26.5, 26.6, which are located on the electrical terminal 14. Two conductor tracks 22.5 and 22.6 connect the two plug pins 26.5, 26.6 of the terminal 14 to two motor plug contacts 28.5 and 28.6.

Via the motor plug contacts 28.5 and 28.6, the actuating drive 18a (see FIG. 3) is electrically triggered and supplied with electrical energy.

The counterpart conductor tracks 24.1, 24.2, 24.3, 24.4 have one sensor terminal 36.1, 36.2, 36.3, and 36.4 on each of their ends. The electrical component 16, or more precisely the angle sensor 16a (see FIG. 2), is connected to the sensor terminals 36.1, 36.2, 36.3, and 36.4.

The ends, toward the counterpart conductor tracks 24.1, 24.2, 24.3, 24.4, of the four conductor tracks 22.1, 22.2, 22.3, 22.4 are all located essentially in the same plane. This plane will hereinafter be called the conductor track plane 30. The ends, toward the conductor tracks 22.1, 22.2, 22.3, 22.4, of the counterpart conductor tracks 24.1, 24.2, 24.3, 24.4 are all located substantially in the same plane. That plane will hereinafter be called the counterpart conductor track plane 32. The conductor track plane 30 and the counterpart conductor track plane 32 are disposed parallel to one another with little spacing. In a viewing direction perpendicular to the planes 30, 32, at least one counterpart conductor track intersects at least one conductor track. The point at which the counterpart conductor track 24.1 intersects the conductor track 22.1 will hereinafter be called the first intersection region 34.1. The first counterpart conductor track 24.1 also intersects the second conductor track 22.2. That point will hereinafter be called the second intersection region 34.2. In the preferably selected exemplary embodiment, the four counterpart conductor tracks 24.1, 24.2, 24.3, 24.4 intersect the four conductor tracks 22.1, 22.2, 22.3, 22.4. The result is a total of sixteen intersection regions 34.1, 34.2, 34.3, 34.4, 34.5, 34.6, 34.7, 34.8, 34.9, 34.10, 34.11, 34.12, 34.13, 34.14, 34.15 and 34.16 between the counterpart conductor tracks 24.1, 24.2, 24.3, 24.4 and the conductor tracks 22.1, 22.2, 22.3, 22.4 (see FIG. 4). The last intersection region, where the counterpart conductor track 24.4 intersects the conductor track 22.4, will hereinafter be called the sixteenth intersection region 34.16. In the preferably selected, especially advantageous exemplary embodiment, the counterpart conductor tracks 24.1, 24.2, 24.3, 24.4 intersect the conductor tracks 22.1, 22.2, 22.3, 22.4 at a right angle, that is, 90°. It should be noted that intersection angles other than 90° are also possible.

In the exemplary embodiment shown, the counterpart conductor track 24.1 is electrically connected to the conductor track 22.1 in the intersection region 34.1. In the intersection region 34.6, the counterpart conductor track 24.2 is electrically connected to the conductor track 22.2. In the intersection region 34.11, the counterpart conductor track 24.3 is electrically connected to the conductor track 22.3. In the intersection region 34.16, the counterpart conductor track 24.4 is electrically to the conductor track 22.4. At the other intersection regions, the counterpart conductor tracks 24.1, 24.2, 24.3, 24.4 are electrically disconnected from the conductor tracks 22.1, 22.2, 22.3, 22.4.

In the exemplary embodiment shown, there are a total of sixteen intersection regions 34.1 through 34.16 between the conductor tracks 22.1, 22.2, 22.3, 22.4 and the counterpart conductor tracks 24.1, 24.2, 24.3, 24.4. Each individual intersection region 34.1 through 34.16 can be designed by simple modification or by a simple provision such that the counterpart conductor track, intersecting the conductor track at the particular intersection region, is either electrically connected to the conductor track, or electrically disconnected from it. It is thus very easily possible, by a simple modification and by a simple provision, to connect the sensor terminal 36.1, for instance, to any arbitrary plug pin 26.1, 26.2, 26.3, 26.4. The same is correspondingly true for the other sensor terminals 36.2, 36.3, 36.4. This has the advantage that every customer can use the plug he wants with a desired electrical assignment of the individual plug pins 26.1, 26.2, 26.3, 26.4, 26.5, 26.6, without requiring complicated retrofitting provisions for the purpose in the production of the control unit 2.

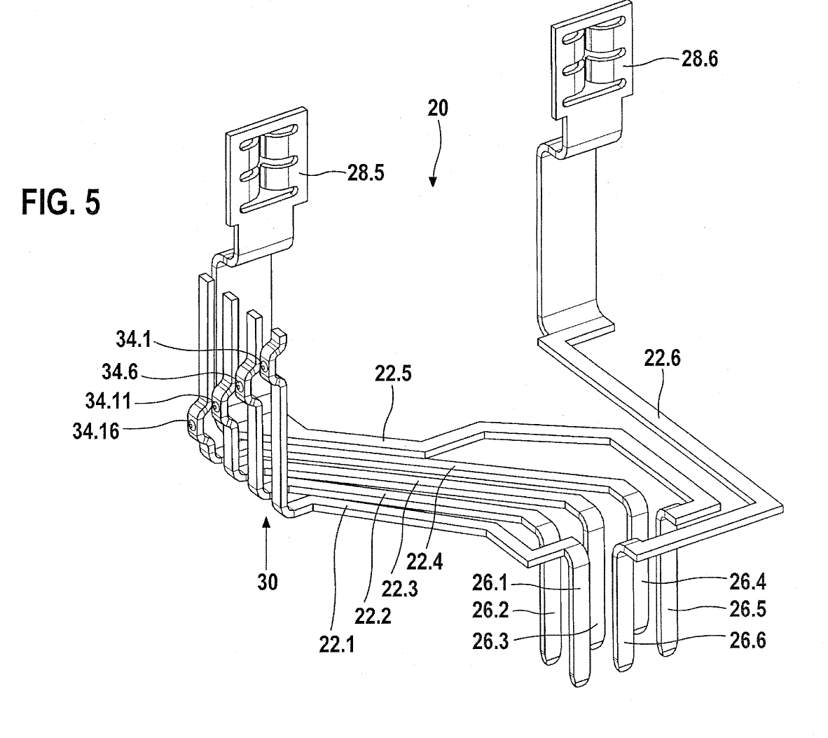

FIG. 5 shows the conductor tracks 22.1, 22.2, 22.3, 22.4, 22.5, 22.6 of the conductor track connection 20 of the connection element 10 without the counterpart conductor tracks 24.1, 24.2, 24.3, 24.4. As can be seen clearly in FIG. 5, the ends of the conductor tracks 22.1, 22.2, 22.3, 22.4 at which, when the control unit 2 is finished, the counterpart conductor tracks 24.1, 24.2, 24.3, 24.4 are electrically connected, are shaped in such a way that they are located in the common plane that is called the conductor track plane 30. At the point where the conductor track 22.1, in the finished state, is intended to have contact with one of the counterpart conductor tracks 24.1, 24.2, 24.3, 24.4, the conductor track 22.1 in the intended intersection region is pivoted out of the conductor track plane 30 in the direction of the counterpart conductor track plane 32. In the exemplary embodiment shown, the conductor track 22.1, in the intersection region 34.1 in which the conductor track 22.1 is supposed to electrically contact the counterpart conductor track 24.1, protrudes somewhat out of the conductor track plane 30 in the direction of the counterpart conductor track 24.1, so that once the counterpart conductor track 24.1 has been added, the conductor track 22.1 electrically contacts the counterpart conductor track 24.1. The same is correspondingly true for the conductor tracks 22.2, 22.3, 22.4, which are shaped in each desired intersection region in such a way that the desired electrical contacting with the particular desired counterpart conductor track 24.1, 24.2, 24.3, 24.4 is ensured.

In the exemplary embodiment shown, the integrally formed-on or stamped or embossed swung-out or thickened or flattened areas, in the desired intersection regions for making the contact between the conductor tracks and the counterpart conductor tracks, are located on the conductor tracks 22.1, 22.2, 22.3, 22.4. However, the control unit 2 may also be modified such that in the intersection regions where electrical contact-making is intended to occur, the swung-out or thickened or flattened areas are provided on both the conductor tracks and the counterpart conductor tracks. The control unit 2 can also be modified such that no swung-out area is provided on the conductor tracks 22.1, 22.2, 22.3, 22.4, but instead the swung-out or thickened or flattened areas are made only on the counterpart conductor tracks 24.1, 24.2, 24.3, 24.4, in those intersection regions 34.1 through 34.16 in which electrical contact is to be made between the conductor tracks and the counterpart conductor tracks of the conductor track connection 20.

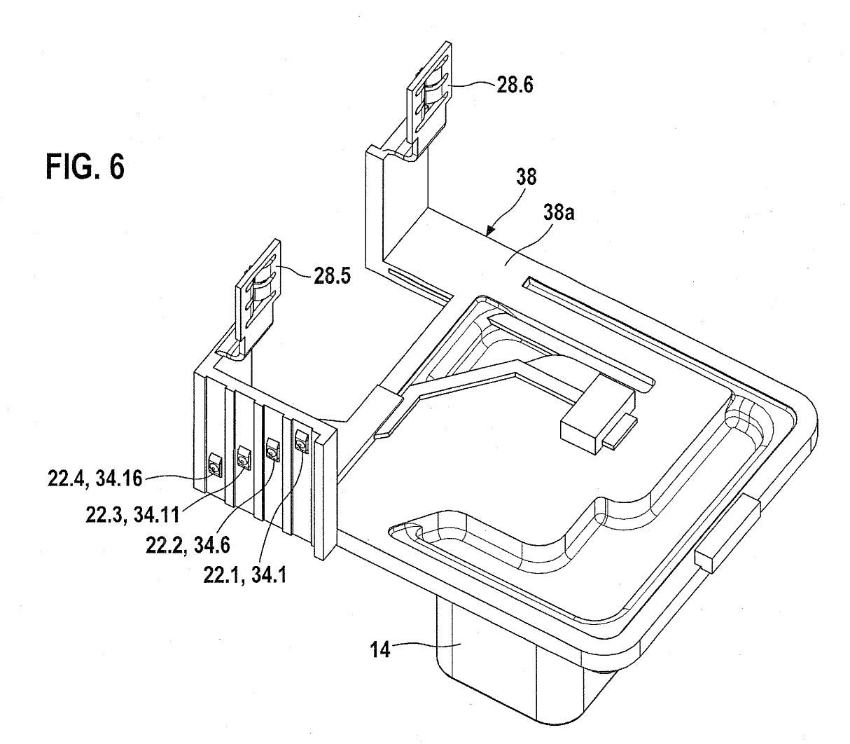

As FIG. 6 shows, the conductor tracks 22.1, 22.2, 22.3, 22.4, 22.5, 22.6 are partly spray-coated with a plastic 38a. As a result, a stable, easily manipulated structure 38 is obtained. For the sake of contact-making, the motor plug contacts 28.5, 28.6 and the plug pins 26.1, 26.2, 26.3, 26.4, 26.5, 26.6 protrude out of the plastic 38a. In the intersection regions 34.1, 34.6, 34.11, and 34.16 where in the exemplary embodiment contact is to be made between the conductor tracks 22.1, 22.2, 22.3, 22.4 and the counterpart conductor tracks 24.1, 24.2, 24.3, 24.4, the conductor tracks 22.1, 22.2, 22.3, 22.4 protrude from the plastic 38a. Because the conductor tracks 22.1, 22.2, 22.3, 22.4 protrude from the plastic 38a only in the intersection regions where electrical contact-making is to occur, in the other intersection regions, an insulation between the conductor tracks 22.1, 22.2, 22.3, 22.4 and the counterpart conductor tracks 24.1, 24.2, 24.3, 24.4 is ensured.

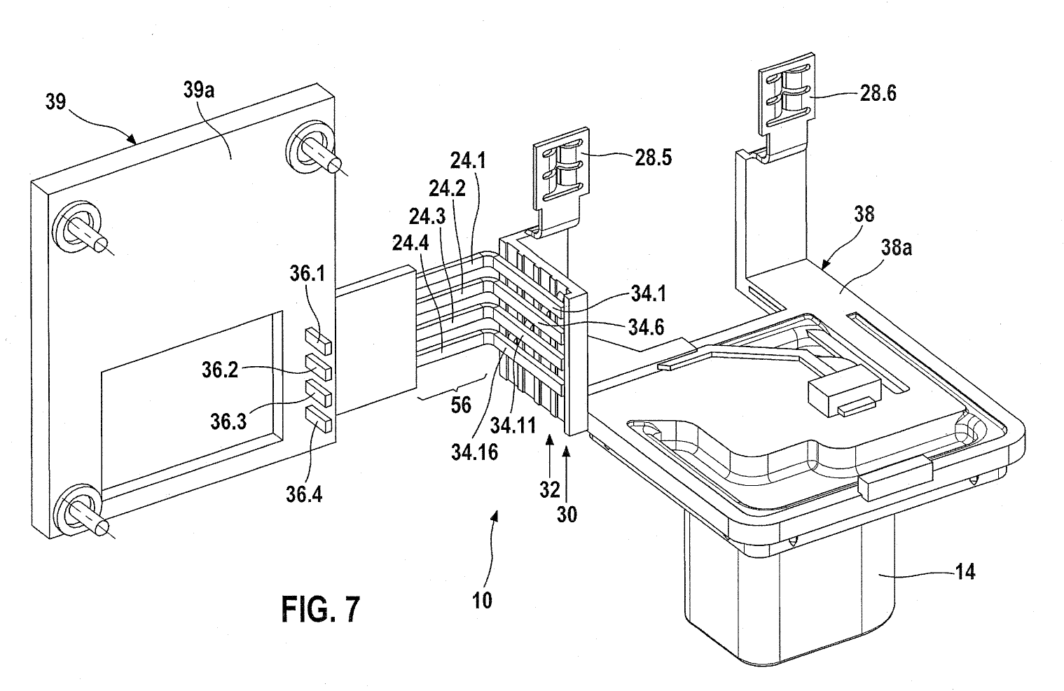

As FIG. 7 shows, the counterpart conductor tracks 24.1, 24.2, 24.3, 24.4 are also spray-coated with a plastic 39a. The sensor terminals 36.1, 36.2, 36.3, 36.4 and the regions, toward the conductor tracks 22.1, 22.2, 22.3, 22.4, of the counterpart conductor tracks 24.1, 24.2, 24.3, 24.4 protrude from the plastic 39a. As a result of the spray-coating with the plastic 39a, a stable, easily manipulated structure 39 is obtained along with the counterpart conductor tracks 24.1, 24.2, 24.3, 24.4. The two structures 38 and 39 spray-coated with the plastics 38a and 39a are joined together, and in the desired intersection regions, for instance in the intersection regions 34.1, 34.6, 34.11, and 34.16, the conductor tracks are connected electrically and mechanically solidly to the counterpart conductor tracks. As a result, the stable, easily manipulated connection element 10 that can be built into the gearbox 12 very simply is obtained.

The connection for instance takes place because the conductor tracks are welded to the counterpart conductor tracks at the desired points. The welding can be done by sending a current surge through the conductor tracks and the counterpart conductor tracks. As a result, the conductor tracks and the counterpart conductor tracks, at the points where they touch one another, are solidly welded together. It is favorable during the welding to press the conductor tracks against the counterpart conductor tracks with moderate force.

In the case of the connection element 10, the conductor track connection 20 is partly spray-coated with the plastics 38a and 39a. As a result, a stable structure that can easily be built in is obtained. The connection element 10 substantially comprises the conductor track connection 20 having the conductor tracks 22.1, 22.2, 22.3, 22.4, 22.5, 22.6, the sensor terminals 36.1, 36.2, 36.3, 36.4, the motor plug contacts 28.5, 28.6, and the plug pins 26.1, 26.2, 26.3, 26.4, 26.5, 26.6, as well as the plastics 38a and 39a.

The electrical components 16, or more precisely the sensor 16a, can be mounted in a simple way and electrically contacted on the sensor terminals 36.1, 36.2, 36.3, 36.4. The stable, easily manipulated connection element 10 with the conductor track connection 20 can be built into the gearbox 12 in a simple way. Without having to make any change in the gearbox 12 itself, it is possible by different contact-making between the conductor tracks and the counterpart conductor tracks to adapt the electrical assignment of the plug pins 26.1, 26.2, 26.3, 26.4, 26.5, 26.6 easily to the particular customer request. All that is required is for a connection element 10, adapted to the customer request, to be built into what is always an identically designed gearbox 12.

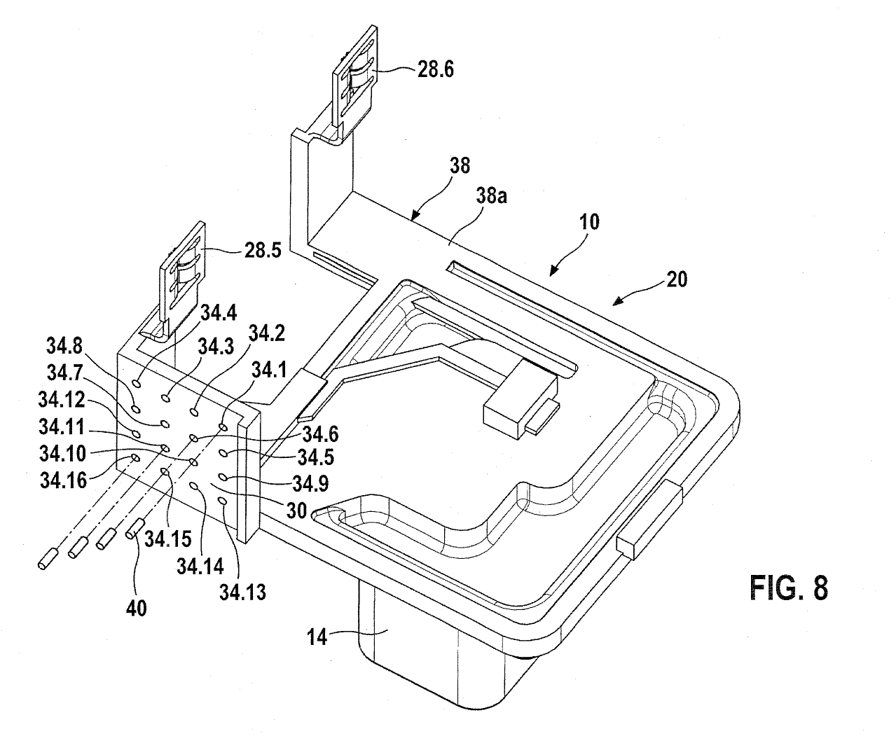

FIG. 8 shows a detail of a modified embodiment of the connection element 10 with the conductor track connection 20 of the control unit 2.

In the version shown in FIG. 8, the ends of the conductor tracks 22.1, 22.2, 22.3, 22.4 are located without a deflection in the conductor track plane 30. In the vicinity of the conductor track plane 30, the conductor tracks 22.1, 22.2, 22.3, 22.4 do not protrude out of the plastic 38a at any point. In the conductor track plane 30, there is a hole in each intersection region 34.1 through 34.16 in which, in the finished state, one of the conductor tracks 22.1, 22.2, 22.3, 22.4 intersects one of the counterpart conductor tracks 24.1, 24.2, 24.3, 24.4. The hole is for instance cylindrical, so that an electrically conductive adapter 40, for instance in the form of a cylindrical metal pin, can be inserted into each of the holes. Normally, a plurality of adapters 40, such as four of them, are used. By way of the adapters 40, the desired contacts can be made between the counterpart conductor tracks and the conductor tracks 22.1, 22.2, 22.3, 22.4, depending on which of the holes in the intersection regions 34.1 through 34.6 the adapters 40 are inserted into. If one adapter 40 is inserted into each of the holes in the four intersection regions 34.1, 34.6, 34.11, 34.16, then the same contact-making as explained as in conjunction with FIG. 4 can be obtained between the conductor tracks and the counterpart conductor tracks. By selective insertion of the adapters 40 into some of the holes in the intersection regions 34.1 through 34.16, any arbitrary combination in terms of the electrical assignment of the plug pins 26.1, 26.2, 26.3, 26.4 can be attained.

If the counterpart conductor tracks are compressed slightly against the conductor tracks and a sufficiently strong current surge is employed, the adapters 40 are welded to the conductor tracks and to the counterpart conductor tracks. As a result, a mechanically and electrically secure connection is obtained between the conductor tracks 22.1, 22.2, 22.3, 22.4 and the counterpart conductor tracks 24.1, 24.2, 24.3, 24.4 of the conductor track connection 20 of the connection element 10 of the control unit 2. Optionally, it is practical to make the weld connection between the particular conductor track and the adapter 40, on the one hand, and the weld connection between the particular counterpart conductor track and the adapter 40, on the other, in a plurality of steps with a plurality of current surges.

It should also be noted that the counterpart conductor track plane 32, in which the ends, toward the conductor tracks, of the counterpart conductor tracks 24.1, 24.2, 24.3, 24.4 are located, can also be spray-coated with plastic, and corresponding holes can also be provided there, so that in the counterpart conductor track plane 32 as well, the adapters 40 can be securely positioned, and the electrical contact-making takes place at the desired points. As a result, any arbitrary combination of contact-making between the conductor tracks and the counterpart conductor tracks of the conductor track connection 20 can be achieved.

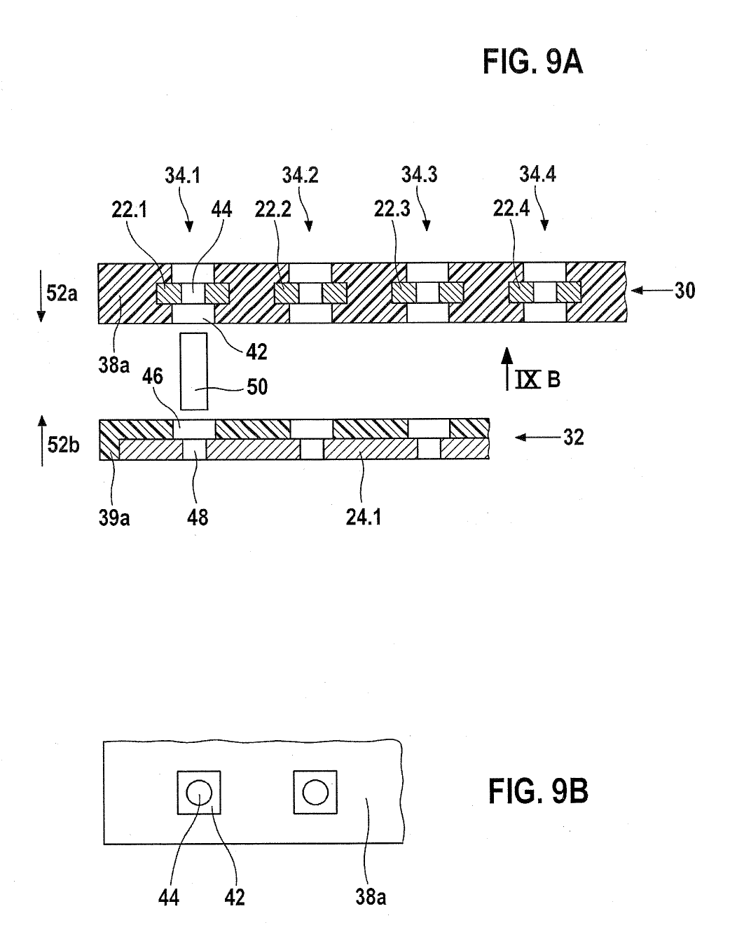

FIGS. 9A and 9B show details of a further modified embodiment of the connection element 10 with the conductor track connection 20 of the control unit 2. What is shown is a state shortly before the conductor track plane 30 and the counterpart conductor track plane 32 of the conductor track connection 20 are joined together.

FIG. 9A shows a section through the modified embodiment of the connection element 10; the section is taken such that the intersection regions 34.1, 34.2, 34.3, and 34.4 are located in the sectional plane. FIG. 9B shows a view to the conductor track plane 30 in which the arrow IXB in FIG. 9A represents the viewing direction.

In this exemplary embodiment, the conductor tracks 22.1, 22.2, 22.3, 22.4 in the vicinity of the conductor track plane 30 are entirely embedded in the plastic 38a. In the vicinity of the counterpart conductor track plane 32, the plastic 39a is sprayed onto the counterpart conductor track 24.1. In precisely the same way, the plastic 39a can also be sprayed onto the remaining counterpart conductor tracks 24.2, 24.3, 24.4. The counterpart conductor tracks 24.1, 24.2, 24.3, 24.4 can also be embedded in the plastic 39a.

In the conductor track plane 30, there is a hole 42 in the plastic 38a. A hole 44 is provided in the conductor track 22.1. In the counterpart conductor track plane 32, there is a hole 46 in the plastic 39a. A hole 48 is also provided in the counterpart conductor track 24.1. The holes 42, 44, 46 and 48 are concentric to one another, and the axes of these holes 42, 44, 46 and 48 are perpendicular to the planes 30, 32 and are located in the intersection region 34.1.

Between the planes 30, 32, there is a plug pin 50.

In FIG. 9A, two arrows 52a and 52b can be seen. During the assembly of the conductor track connection 20, the conductor track plane 30 and the counterpart conductor track plane 32 are pressed against one another in the direction of the arrows 52a and 52b. In the process, the plug pin 50 is introduced into the hole 42 and into the hole 46. If the two planes 30, 32 are pressed against one another with sufficiently great force, then the plug pin 50 is pressed or rammed into the hole 44 and into the hole 48. The plug pin 50 can therefore also be called a ram pin.

The plug pin 50 and the holes 42, 46 have a square cross section, for example, and the holes 44, 48 have a round cross section, for example. The cross sections are adapted to one another in such a way that the plug pin 50 can be introduced into the holes 42, 46 without expending force, and the holes 44, 48 are dimensioned such that the plug pin 50 can be forced into them only with considerable expenditure of force, so that secure durable electrical contact-making is ensured. The press-fitted-in plug pin 50, in the desired intersection region, ensures a secure connection between the conductor track 22.1 and the counterpart conductor track 24.1. The other intersection regions can be embodied in the same way as the intersection region 34.1. Only in those intersection regions in which electrical contact-making is desired are further plug pins 50 provided.

Depending on the customer request, the body 4 (FIG. 1) adjustably supported in the control unit 2 is of variable size. More precisely, the diameter of the throttle valve 4a can be of variable size, depending on the customer request. In a particularly large body 4 or a particularly small body 4, the spacing between the throttle valve shaft 4b and the electrical terminal 14 must be adapted accordingly. This can be done very easily in the proposed control unit 2, for instance by making a protruding region 56 of the counterpart conductor tracks 24.1, 24.2, 24.3, 24.4, which protrudes past the plastic 39a in the direction of the conductor tracks 22.1, 22.2, 22.3, 22.4, more or less long to suit the desired spacing (see FIG. 7). This has the advantage that this can be done simply, without having to modify the shape for the plastic 39a and/or the shape for the plastic 38a.

As FIG. 6 shows, the conductor tracks 22.1, 22.2, 22.3, 22.4 in the vicinity of the conductor track plane 30 are spray-coated with the plastic 38a, and only individual regions of the conductor tracks 22.1, 22.2, 22.3, 22.4 protrude past the plastic 38a, so that no short-circuiting or contact-making can occur at unwanted points. The connection element 10 of the control unit 2 may, however, also be modified such that in the vicinity of the contact-making between the conductor tracks and the counterpart conductor tracks, it is not the conductor tracks that are spray-coated with the plastic 38a, but instead the counterpart conductor tracks 24.1, 24.2, 24.3, 24.4 in the vicinity of the counterpart conductor track plane 32 are spray-coated with the plastic 39a, in order to prevent contact-making at the unwanted points and to avoid a short circuit.

In the exemplary embodiments shown, the motor plug contact 28.5 at which the actuating drive 18a is electrically connected, is not variably connected to the plug pin 26.5. Nor is the other motor plug contact 28.6 variably electrically connected to the plug pin 26.6. It should be noted that the control unit 2 can be modified such that the motor plug contacts 28.5 and 28.6 can also be connected in such a way and integrated with the conductor track connection 20 that even after electrical contact-making between the conductor tracks and the counterpart conductor tracks, any arbitrary plug pin of the electrical terminal 14 can be electrically associated with the motor plug contacts 28.5 and 28.6.

In the preferably selected, especially advantageous exemplary embodiments, the counterpart conductor tracks and the conductor tracks intersect at a right angle in the intersection regions 34.1 through 34.16. It should be noted that this need not necessarily be a right angle, but instead an intersection angle deviating from that is also possible.

The conductor tracks 22.1, 22.2, 22.3, 22.4, 22.5, 22.6 can for instance be stamped out of a sheet-metal plate and are therefore also called a stamped grating. The counterpart conductor tracks 24.1, 24.2, 24.3, 24.4 can also be called a stamped grating. In the proposed control unit 2, between the two stamped gratings a matrixlike connection region is created, in which any arbitrary polarization between one stamped grating and the other stamped grating can be established between the two stamped gratings in the connection region. All that is ever changed is the matrix region of one stamped grating, so that large groups of the manufacturing tools can remain unchanged.

A method for producing the control unit 2 is also proposed, in which in the intersection region 34.1 through 34.16 of the intersecting conductor track 22.1 through 22.6 and counterpart conductor track 24.1 through 24.4, the electrical connection between the conductor track 22.1 through 22.6 and the counterpart conductor track 24.1 through 24.4 can be defined as a function of a desired electrical assignment of the electrical terminal 14 of the connection element 10.

1-19. (canceled)

20. A control unit, comprising:
an adjustably supported body;
at least one electrically connected component;
an electrical terminal for electrically connecting the at least one electrically connected component to an electrical device; and
a conductor track connection for electrically connecting the electrically connected components to the electrical terminal, the conductor track connection having at least one conductor track, at least one counterpart conductor track, and at least one intersection region, and in the intersection region, the at least one conductor track and the at least one counterpart conductor track intersect.

21. The control unit as defined by claim 20, wherein the conductor track connection has a plurality of intersection regions.

22. The control unit as defined by claim 20, wherein the conductor track connection includes a plurality of conductor tracks.

23. The control unit as defined by claim 21, wherein the conductor track connection includes a plurality of conductor tracks.

24. The control unit as defined by claim 20, wherein the conductor track connection includes a plurality of counterpart conductor tracks.

25. The control unit as defined by claim 20, wherein the at least conductor track and the at least one counterpart conductor track are electrically connected to one another in the at least one intersection region.

26. The control unit as defined by claim 20, wherein the control unit has, as an electrically connected component, a sensor for sensing a position of the adjustably supported body.

27. The control unit as defined by claim 20, wherein the control unit has, as an electrically connected component, an actuating drive for adjusting the adjustably support body.

28. The control unit as defined by claim 20, wherein the at least one conductor track is pivoted in the intersection region in a direction of the counterpart conductor track.

29. The control unit as defined by claim 20, wherein the at least one counterpart conductor track is pivoted in the intersection region in a direction of the conductor track.

30. The control unit as defined by claim 20, wherein in the intersection region between the conductor track and the counterpart conductor track, the at least one conductor track extends essentially in a conductor track plane, and the at least one counterpart conductor track extends essentially in a counterpart conductor track plane, and the two planes are disposed with little spacing from one another.

31. The control unit as defined by claim 30, wherein the at least one conductor track is pivoted in the intersection region out of the conductor track plane in a direction of the counterpart conductor track.

32. The control unit as defined by claim 30, wherein the at least one counterpart conductor track in the intersection region is pivoted out of the counterpart conductor track plane in a direction of the conductor track.

33. The control unit as defined by claim 20, wherein between the at least one conductor track and the counterpart conductor track, an adapter electrically connecting the conductor track to the counterpart conductor track is provided.

34. The control unit as defined by claim 20, wherein the at least one conductor track is at least partly spray-coated with plastic.

35. The control unit as defined by claim 20, wherein the at least one counterpart conductor track is at least partly spray-coated with plastic.

36. The control unit as defined by claim 20, wherein the electrical terminal is integrated with a connection element.

37. The control unit as defined by claim 20, wherein the at least one conductor track intersects a plurality of counterpart conductor tracks.

38. The control unit as defined by claim 20, wherein the at least one counterpart conductor track intersects a plurality of conductor tracks.

39. A method for producing a control unit as defined by claim 20, which includes:
defining the electrical connection between the conductor track and the counterpart conductor track, in the intersection region of the conductor track intersecting with the counterpart conductor track, as a function of a desired electrical assignment for the electrical terminal.
